(19) United States
(12) Patent Application Publication
(10) Pub. No.: US 2016/0322597 A1
(43) Pub. Date: Nov. 3, 2016

(54) MATERIAL FOR SEALING DISPLAY APPARATUS, ORGANIC LIGHT-EMITTING DISPLAY APPARATUS COMPRISING THE SAME, AND METHOD OF MANUFACTURING THE ORGANIC LIGHT-EMITTING DISPLAY APPARATUS

(71) Applicants: SAMSUNG DISPLAY CO., LTD., Yongin-si (KR); YAMATO ELECTRONIC CO., LTD., Kagoshima (JP)

(72) Inventors: Sucheol Gong, Yongin-si (KR); Hyunmin Hwang, Yongin-si (KR); Hyunyoung Kim, Yongin-si (KR); Soukjune Hwang, Yongin-si (KR)

(21) Appl. No.: 15/002,341

(22) Filed: Jan. 20, 2016

(30) Foreign Application Priority Data
Apr. 28, 2015 (KR) 10-2015-0060080

(51) Int. Cl. H01L 51/52; C04B 35/495; H01L 51/56

(52) U.S. Cl. CPC H01L 51/5246; H01L 51/56; C04B 35/495; H01L 2251/303; H01L 2251/301

(57) ABSTRACT

A material for sealing a display apparatus, the material having an improved mechanical strength and improved flowability, an organic light-emitting display apparatus including the material, and a method of manufacturing the organic light-emitting display apparatus are provided. The organic light-emitting display apparatus includes a lower substrate having a display area and a peripheral area around the display area; a display unit on the display area of the lower substrate; an upper substrate on the display unit and facing the lower substrate; and a sealing member on the peripheral area of the lower substrate to adhere the lower substrate and the upper substrate together, the sealing member including a glass powder, a first filler including a ceramic material, and a second filler including iron oxide.

### CROSS-REFERENCE TO RELATED PATENT APPLICATION

This application claims priority to and the benefit of Korean Patent Application No. 10-2015-0060080, filed on Apr. 28, 2015, in the Korean Intellectual Property Office, the entire content of which is incorporated herein by reference.

### BACKGROUND

1. Field

One or more exemplary embodiments relate to a material for sealing a display apparatus, an organic light-emitting display apparatus including the material, and a method of manufacturing the organic light-emitting display apparatus, and, for example, to a material for sealing a display apparatus, the material having an improved mechanical strength and improved flowability, an organic light-emitting display apparatus including the material, and a method of manufacturing the organic light-emitting display apparatus.

2. Description of the Related Art

Organic light-emitting display apparatuses have a larger viewing angle, better contrast characteristics, and a faster response speed than other display apparatuses, and thus, have drawn attention as a next-generation display apparatus.

In general, organic light-emitting display apparatuses include thin film transistors and organic light emitting diodes on (e.g., formed on) a substrate, and the organic light emitting diodes emit light. Such organic light-emitting display apparatuses may be used as display units of small products, such as mobile phones, and may also be used as display units of large products, such as televisions.

Such organic light-emitting display apparatuses are structured such that a lower substrate having thin film transistors, organic light-emitting devices, and a wiring pattern on (e.g., formed thereon) is sealed utilizing an upper substrate. For example, the lower substrate and the upper substrate are adhered to each other by coating the perimeter of the lower substrate with a sealing material, mounting the upper substrate on the resultant lower substrate, and hardening the sealing material by using a method such as, for example, radiation of ultraviolet rays (UVs). The sealing material is formed of a glass frit and a filler with which the glass frit is filled.

### SUMMARY

In the above-described organic light-emitting display apparatus, when the filler is added to the glass frit, the sealing material has an improved mechanical strength but has degraded flowability, and accordingly, handling of the sealing material is not easy during the manufacture of an organic light-emitting display apparatus and binding power between the sealing material and the lower and upper substrates is low.

One or more exemplary embodiments include a material for sealing a display apparatus, the material having an improved mechanical strength and improved flowability, an organic light-emitting display apparatus including the material, and a method of manufacturing the organic light-emitting display apparatus. However, the one or more embodiments are only examples, and the scope of the present invention is not limited thereto.

Additional aspects will be set forth in part in the description which follows and, in part, will be apparent from the description, or may be learned by practice of the presented embodiments.

According to one or more exemplary embodiments, an organic light-emitting display apparatus includes: a lower substrate having a display area and a peripheral area around the display area; a display unit disposed on the display area of the lower substrate; an upper substrate disposed on the display unit to face the lower substrate; and a sealing member disposed on the peripheral area of the lower substrate to adhere the lower substrate and the upper substrate together, the sealing member including a glass powder, a first filler including a ceramic material, and a second filler including iron oxide.

The iron oxide included in the second filler may be Fe₂O₃.

A crystalline particle of the iron oxide may have a diameter of about 0.1 to about 2 μm.

The first filler may include a low thermal expansion ceramic material having a Coefficient of Thermal Expansion (CTE) of (−90 to 50)*10⁻⁷/K or less.

The first filler may include at least one selected from the group consisting zirconium (Zr)-based ceramic, cordierite, amorphous silica, eucryptite, aluminum titanate, spodumene, willemite, and mulite.

The glass powder may be formed of V₂O₅ of 30 to 50 mol %, ZnO of 5 to 30 mol %, BaO of 0 to 20 mol %, TeO₂ of 0 to 30 mol %, Nb₂O₅ of 0 to 7 mol %, Al₂O₃ of 0 to 7 mol %, SiO₂ of 0 to 7 mol %, CuO of 0 to 5 mol %, MnO₂ of 0 to 5 mol %, and CaO of 0 to 5 mol %.

The sealing member may include the glass powder of 50 to 90 wt %, the first filler of 1 to 50 wt %, and the second filler of 1 to 5 wt %.

According to one or more exemplary embodiments, a method of manufacturing an organic light-emitting display apparatus, includes: preparing for a lower substrate having a display area and a peripheral area around the display area; forming a display unit on the display area of the lower substrate; forming a sealing material on the peripheral area of the lower substrate, the sealing material including a glass powder, a first filler including a ceramic material, and a second filler including iron oxide; and positioning the upper substrate on the lower substrate and then adhering the lower substrate to the upper substrate via the sealing material.

The iron oxide included in the second filler may be Fe₂O₃.

A crystalline particle of the iron oxide may have a diameter of about 0.1 to about 2 μm.

The first filler may include a low thermal expansion ceramic material having a Coefficient of Thermal Expansion (CTE) of (−90 to 50)*10⁻⁷/K or less.

The first filler may include at least one selected from the group consisting zirconium (Zr)-based ceramic, cordierite, amorphous silica, eucryptite, aluminum titanate, spodumene, willemite, and mulite.

The glass powder may be formed of V₂O₅ of 30 to 50 mol %, ZnO of 5 to 30 mol %, BaO of 0 to 20 mol %, TeO₂ of 0 to 30 mol %, Nb₂O₅ of 0 to 7 mol %, Al₂O₃ of 0 to 7 mol %, SiO₂ of 0 to 7 mol %, CuO of 0 to 5 mol %, MnO₂ of 0 to 5 mol %, and CaO of 0 to 5 mol %.

The sealing member may include the glass powder of 50 to 90 wt %, the first filler of 1 to 50 wt %, and the second filler of 1 to 5 wt %.

The adhering of the lower substrate to the upper substrate may include adhering the lower substrate to the upper substrate by radiating laser to the upper substrate or the lower substrate on which the sealing material is formed (or located).

According to one or more exemplary embodiments, a material for sealing a display apparatus, includes: V₂O₅-based glass powder; a first filler including a ceramic material; and a second filler comprising iron oxide.

The iron oxide included in the second filler may be Fe₂O₃.

A crystalline particle of the iron oxide has a diameter of about 0.1 to about 2 μm.

The first filler may include a low thermal expansion ceramic material having a Coefficient of Thermal Expansion (CTE) of (30 to 90)*10⁻⁷/K or less.

The first filler may include at least one selected from the group consisting zirconium (Zr)-based ceramic, cordierite, amorphous silica, eucryptite, aluminum titanate, spodumene, willemite, and mulite.

The glass powder may be formed of V₂O₅ of 30 to 50 mol %, ZnO of 5 to 30 mol %, BaO of 0 to 20 mol %, TeO₂ of 0 to 30 mol %, Nb₂O₅ of 0 to 7 mol %, Al₂O₃ of 0 to 7 mol %, SiO₂ of 0 to 7 mol %, CuO of 0 to 5 mol %, MnO₂ of 0 to 5 mol %, and CaO of 0 to 5 mol %.

The sealing member may include the glass powder of 50 to 90 wt %, the first filler of 1 to 50 wt %, and the second filler of 1 to 5 wt %.

### BRIEF DESCRIPTION OF THE DRAWINGS

These and/or other aspects of embodiments will become apparent and more readily appreciated from the following description of the embodiments, taken in conjunction with the accompanying drawings in which:

FIG. 1 is a schematic partial plan view of an organic light-emitting display device according to an embodiment of the present disclosure;

FIG. 2 is a schematic cross-sectional view taken along line II-II of the organic light-emitting display apparatus of FIG. 1;

FIG. 3 is a cross-sectional view illustrating a structure of a display unit of FIG. 2 in greater detail;

FIG. 4 is a magnified diagram of a portion of a sealing member of FIG. 2;

FIG. 5 is a graph showing measured viscosity of a sealing material according to an embodiment of the present disclosure and measured viscosity of a sealing material of a comparative example with respect to temperature;

FIG. 6 is a table showing measured values of mechanical strengths of a sealing material according to an embodiment of the present disclosure and a sealing material according to a comparative example of FIG. 5; and

FIGS. 7-9 are cross-sectional views schematically illustrating a method of manufacturing an organic light-emitting display apparatus, according to an embodiment of the present disclosure.

### DETAILED DESCRIPTION

Reference will now be made in more detail to certain embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of embodiments of the present description. As used herein, the term “and/or” includes any and all combinations of one or more of the associated listed items. Expressions such as “at least one of” when preceding a list of elements, modify the entire list of elements and do not modify the individual elements of the list.

Spatially relative terms, such as “beneath,” “below,” “lower,” “under,” “above,” “upper,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below (e.g., the upper substrate may be above or below the lower substrate). The device may be otherwise oriented (e.g., rotated 90 degrees or at other orientations) and the spatially relative descriptors used herein should be interpreted accordingly.

One or more embodiments of the present disclosure will be described below in more detail with reference to the accompanying drawings. Those components that are the same or are in correspondence with each other are rendered utilizing the same reference numeral regardless of the figure number, and redundant explanations thereof are necessary and are not provided.

It will be understood that although the terms “the first”, “the second”, etc. may be used herein to describe various components, these components should not be limited by these terms. These terms are only used to distinguish one component from another. As used herein, the singular forms “a”, “an” and “the” are intended to include the plural forms as well, unless the context clearly indicates otherwise.

It will be further understood that the terms “comprises” and/or “comprising” used herein specify the presence of stated features or components, but do not preclude the presence or addition of one or more other features or components. It will be understood that when a layer, region, or component is referred to as being “on,” “formed on,” “connected to,” or “coupled to” another layer, region, or component, it can be directly or indirectly on, formed on, connected to, or coupled to the other layer, region, or component. That is, for example, intervening layers, regions, or components may be present. In addition, it will also be understood that when an element or layer is referred to as being “between” two elements or layers, it can be the only element or layer between the two elements or layers, or one or more intervening elements or layers may also be present.

Sizes of elements in the drawings may be exaggerated for convenience of explanation. In other words, since sizes and thicknesses of components in the drawings may be arbitrarily illustrated for convenience of explanation, the following embodiments are not limited thereto.

As used herein, the term “substantially,” “about,” and similar terms are used as terms of approximation and not as terms of degree, and are intended to account for the inherent deviations in measured or calculated values that would be recognized by those of ordinary skill in the art. Further, the use of “may” when describing embodiments of the present disclosure refers to one or more embodiments of the present disclosure.” As used herein, the terms “use,” “using,” and “used” may be considered synonymous with the terms “utilize,” “utilizing,” and “utilized,” respectively. Also, the term “exemplary” is intended to refer to an example or illustration.

In the following examples, the x-axis, the y-axis and the z-axis are not limited to three axes of the rectangular coordinate system, and may be interpreted in a broader sense. For example, the x-axis, the y-axis, and the z-axis may be perpendicular or substantially perpendicular to one another, or may represent different directions that are not perpendicular to one another.

When a certain embodiment may be implemented differently, a specific process order may be performed differently from the described order. For example, two consecutively described processes may be performed substantially at the same time or performed in an order opposite to the described order.

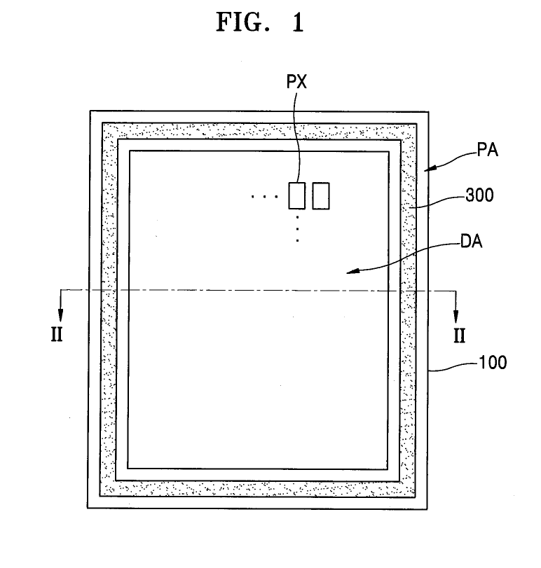

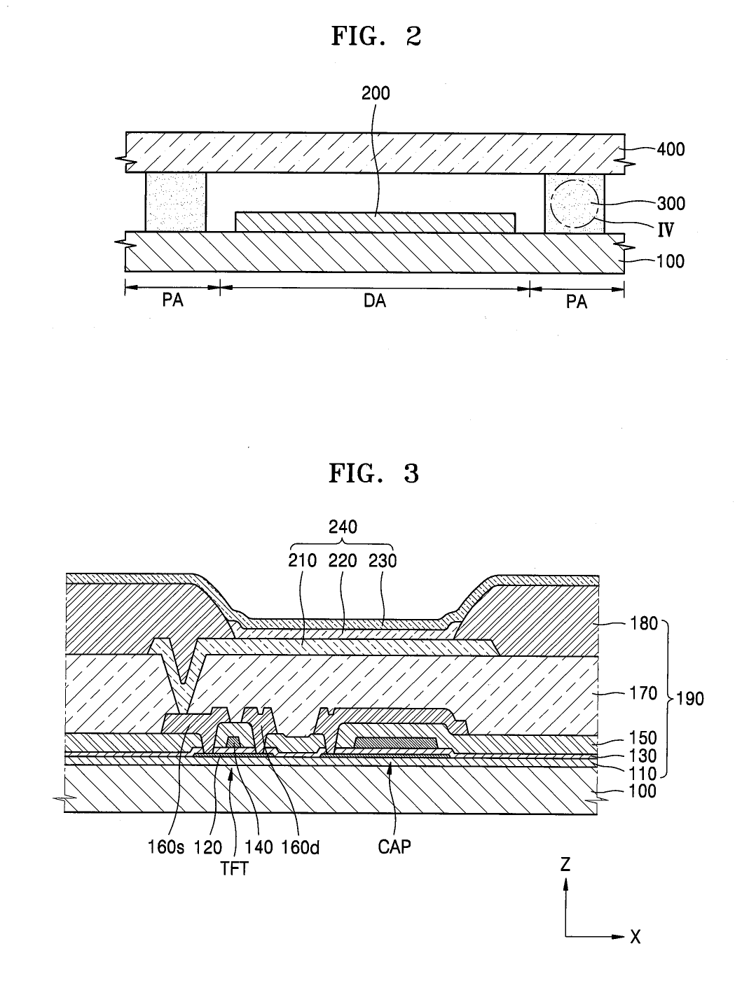

FIG. 1 is a schematic plan view of an organic light-emitting display apparatus according to an embodiment of the present disclosure. FIG. 2 is a schematic cross-sectional view obtained by taking the organic light-emitting display apparatus of FIG. 1 along line II-II.

Referring to FIGS. 1 and 2, the organic light-emitting display apparatus includes a lower substrate 100, a display unit 200 disposed on the lower substrate 100, an upper substrate 400 facing the lower substrate 100, and a sealing member 300 bonding (e.g., adhering) the lower substrate 100 to the upper substrate 400.

The lower substrate 100 may be formed of a transparent glass material containing SiO₂ as a main component. However, the material used to form the lower substrate 100 is not limited thereto, and the lower substrate 100 may be formed of a transparent plastic material. The plastic material used to form the lower substrate 100 may be an organic insulating material selected from the group consisting of polyethersulphone (PES), polyacrylate (PAR), polyetherimide (PEI), polyethylene naphthalate (PEN), polyethylene terephthalate (PET), polyphenylene sulfide (PPS), polyallylate, polyimide, polycarbonate (PC), cellulose triacetate (TAC), and cellulose acetate propionate (CAP).

As for a bottom-emission organic light-emitting display apparatus that displays an image on the lower substrate 100, the lower substrate 100 may be formed of a transparent material. As for a top-emission organic light-emitting display apparatus that displays an image in a direction away from the lower substrate 100, the lower substrate 100 does not need to be formed of a transparent material. For example, the lower substrate may include a reflective material. In this case, the lower substrate 100 may be formed of a metal. The metal that may be used to form the lower substrate 100 may include at least one metal selected from the group consisting of iron (Fe), chromium (Cr), manganese (Mn), nickel (Ni), titanium (Ti), molybdenum (Mo), stainless steel (SUS), an Invar alloy, an Inconel alloy, and a Kovar alloy. The lower substrate may include carbon (C) in addition to or instead of the metal. However, the lower substrate 100 is not limited thereto.

A buffer layer may be on (e.g., formed on) an upper surface of the lower substrate 100 in order to smoothen the lower substrate 100 and to prevent or reduce permeation of impure elements (e.g., to prevent or reduce permeation of impurities into the organic light-emitting display apparatus). The lower substrate 100 may have a display area DA in which a plurality of pixels PX are disposed, and a peripheral area PA that surrounds the display area DA.

The upper substrate 400 may be disposed over the upper surface of the lower substrate 100 including the display unit 200. The upper substrate 400 may be disposed on the display unit 200 so as to face the lower substrate 100, and may be adhered to the lower substrate 100 via the sealing member 300, which will be described in more detail later.

The upper substrate 400 may be any suitable substrate formed of various suitable materials. For example, the upper substrate 400 may be a glass substrate, like some embodiments of the lower substrate 100, may be a plastic substrate such as an acryl substrate, or may be a metal plate. In this case, as for a top-emission organic light-emitting display apparatus that displays an image on or through the upper substrate 400, the upper substrate 400 may be formed of a transparent material. As for a top-emission organic light-emitting display apparatus that displays an image in a direction away from the lower substrate 100, the lower substrate 100 does not need to be formed of a transparent material (e.g., the lower substrate may be reflective).

The display unit 200 may be disposed on the lower substrate 100 and may include the plurality of pixels PX. For example, each pixel PX may include a plurality of thin film transistors TFT and organic light-emitting devices (OLEDs) 240 (see FIG. 3) that are electrically coupled or connected to the respective thin film transistors TFT. An embodiment of a structure of the display unit 200 will be described later in more detail with reference to FIG. 3.

The sealing member 300 may be disposed on the peripheral area PA of the lower substrate 100, and the lower substrate 100 and the upper substrate 400 may be adhered together via the sealing member 300. The sealing member 300 may be disposed apart (e.g., set apart) by a set or predetermined distance from the display unit 200 disposed in the display area DA, and may also be disposed (e.g., located) a set or predetermined distance inward from the edge of the lower substrate 100. The sealing member 300 may be, for example, glass frit. The sealing member 300 adheres the lower substrate 100 and the upper substrate 400 together, for example, as described above, and the display unit 200 may be sealed by the sealing member 300.

FIG. 3 is a cross-sectional view illustrating a structure of the display unit 200 of FIG. 2 in greater detail.

Referring to FIG. 3, a thin film transistor layer 190 is disposed on the lower substrate 100, and may include a thin film transistor TFT and a capacitor CAP thereon (e.g., formed thereon). An OLED 240 electrically coupled or connected to the thin film transistor TFT may be positioned on the thin film transistor layer 190. The thin film transistor TFT includes a semiconductor layer 120 including amorphous silicon, crystalline silicon, or an organic semiconductor material, a gate electrode 140, a source electrode 160s, and a drain electrode 160d. A structure of the thin film transistor TFT will now be described in more detail.

To planarize the surface of the lower substrate 100 and/or prevent impurities and/or the like from permeating the semiconductor layer 120 of the thin film transistor TFT (or to reduce such permeation of impurities), a buffer layer 110 formed of a silicon oxide, a silicon nitride, and/or the like may be disposed on the lower substrate 100, and the semiconductor layer 120 may be located on the buffer layer 110.

The gate electrode 140 is disposed on the semiconductor layer 120, and the source electrode 160s and the drain electrode 160d electrically communicate with each other in response to a signal applied to the gate electrode 140. For example, the gate electrode 140 may be formed of at least one selected from aluminum (Al), platinum (Pt), palladium (Pd), silver (Ag), magnesium (Mg), gold (Au), nickel (Ni), neodymium (Nd), iridium (Ir), chromium (Cr), calcium (Ca), molybdenum (Mo), titanium (Ti), tungsten (W), and copper (Cu) in a single- or multi-layered structure, in consideration of adhesion to an adjacent layer, surface smoothness of a layer stacked on the gate electrode 140, and/or processability.

To secure insulation between the semiconductor layer 120 and the gate electrode 140, a gate insulation layer 130 formed of a silicon oxide and/or a silicon nitride may be interposed between the semiconductor layer 120 and the gate electrode 140.

An interlayer insulation layer 150 may be disposed on the gate electrode 140 and may be formed of a silicon oxide, a silicon nitride, or the like in a single- or multi-layered structure.

The source electrode 160s and the drain electrode 160d are disposed on the interlayer insulation layer 150. The source electrode 160s and the drain electrode 160d may be electrically coupled or connected to the semiconductor layer 120 via contact holes in (e.g., formed in) the interlayer insulation layer 150 and the gate insulation layer 130. For example, the source electrode 160s and the drain electrode 160d may each be formed of at least one selected from aluminum (Al), platinum (Pt), palladium (Pd), silver (Ag), magnesium (Mg), gold (Au), nickel (Ni), neodymium (Nd), iridium (Ir), chromium (Cr), calcium (Ca), molybdenum (Mo), titanium (Ti), tungsten (W), and copper (Cu) in a single- or multi-layered structure, in consideration of conductivity or the like.

A protective layer may be disposed on the thin film transistor TFT to protect the thin film transistor TFT having this structure. The protective layer may be formed of an inorganic material such as silicon oxide, silicon nitride, or silicon oxynitride.

A first insulation layer 170 may be disposed on the lower substrate 100. In this case, the first insulation layer 170 may be a planarization layer or a protective layer. When an OLED is disposed on the thin film transistor TFT, the first insulation layer 170 mostly planarizes the upper surface of the thin film transistor TFT and protects the thin film transistor TFT and various devices (e.g., protects various components covered by the first insulation layer). The first insulation layer 170 may be formed of, for example, an acryl-based organic material or benzocyclobutene (BCB). In this case, as shown in FIG. 3, the buffer layer 110, the gate insulation layer 130, the interlayer insulating layer 150, and the first insulation layer 170 may be on (e.g., formed on) the entire surface of the lower substrate 100.

A second insulation layer 180 may be disposed on the thin film transistor TFT. In this case, the second insulation layer 180 may be a pixel defining layer. The second insulation layer 180 may be positioned on the first insulation layer 170 and may have an aperture. The second insulation layer 180 defines pixel areas on the lower substrate 100.

The second insulation layer 180 may be, for example, an organic insulation layer. The organic insulation layer may include an acryl-based polymer such as polymethyl methacrylate (PMMA), polystyrene (PS), a polymer derivative having a phenol group, an imide-based polymer, an acryl ether-based polymer, an amide-based polymer, a fluorine-based polymer, a p-xylene-based polymer, a vinyl alcohol-based polymer, or a mixture of these materials.

The OLED 240 may be disposed on the second insulation layer 180. The OLED 240 may include a pixel electrode 210, an intermediate layer 220 including an emission layer (EML), and an opposite electrode 230.

The pixel electrode 210 may be formed as a transparent (or semi-transparent) electrode or a reflective electrode. When the pixel electrode 210 is formed as a transparent (or semi-transparent) electrode, the pixel electrode 210 may be formed of, for example, indium tin oxide (ITO), indium zinc oxide (IZO), zinc oxide (ZnO), indium oxide (In₂O₃), indium gallium oxide (IGO), or aluminum zinc oxide (AZO). When the pixel electrode 210 is formed as a reflective electrode, the pixel electrode 210 may include a reflective layer formed of silver (Ag), magnesium (Mg), aluminum (Al), platinum (Pt), palladium (Pd), gold (Au), nickel (Ni), neodymium (Nd), iridium (Ir), chromium (Cr), or a combination thereof, and a layer formed of ITO, IZO, ZnO, In₂O₃, IGO, or AZO. Of course, embodiments of the present disclosure are not limited thereto, and the pixel electrode 210 may be formed of any of various other suitable materials and may have any of various suitable structures, such as, a single- or multi-layered structure.

The intermediate layer 220 may be disposed on each of the pixel areas defined by the second insulation layer 180. The intermediate layer 220 includes an EML that emits light according to an electrical signal, and may further include at least one layer selected from a hole injection layer (HIL) disposed between the EML and the pixel electrode 210, a hole transport layer (HTL), an electron transport layer (ETL) disposed between the EML and the opposite electrode 230, and an electron injection layer (EIL). The at least one layer is stacked in a single- or multi-layered stack structure. The intermediate layer 220 is not limited to the structure described above, and may have any of various other suitable structures. The HTL, the HIL, the ETL, and/or the EIL may be integrally on (e.g., formed on) the entire or substantially the entire surface of the lower substrate 100, and only the EML may be on (e.g., formed on) each of the pixel areas via inkjet printing, but the present disclosure is not limited thereto.

The intermediate layer 220 may be formed of a low-molecular organic material (e.g., a low-molecular weight organic material) or a high-molecular organic material (e.g., a high-molecular weight organic material).

When the intermediate layer 220 is a low molecular organic layer, a HTL, an HIL, an EML, an ETL, and an EIL may be sequentially stacked. Various other suitable layers may be further stacked if necessary or desired. Examples of organic materials that may be used to form the intermediate layer 220 (e.g., examples of the low molecular weight organic materials) include any of various suitable materials such as copper phthalocyanine (CuPc), N′-Di(naphthalene-1-yl)-N,N′-diphenyl-benzidine (NPB), and tris-8-hydroxyquinoline aluminum (Alq3).

On the other hand, when the intermediate layer 220 is a high-molecular organic layer, an HTL may be provided in addition to the intermediate layer 220. The HTL may be formed of poly-2,4-ethylene-dihydroxy thiophene (poly(ethylenedioxythiophene)), polyaniline (PANI), or the like. In this case, examples of organic materials that may be used to form the intermediate layer 220 include high-molecular organic materials such as polyphenylene vinylene (PPV) and polyfluorene. An inorganic material may be further included between the intermediate layer 220 and the pixel electrode 210 and between the intermediate layer 220 and the opposite electrode 230.

The opposite electrode 230 covers or substantially covers the intermediate layer 220 including the EML and faces the pixel electrode 210. The opposite electrode 230 may be disposed on the entire surface of the lower substrate 100. The opposite electrode 230 may be formed as a transparent (or semi-transparent) electrode or a reflective electrode.

When the opposite electrode 230 is formed as a transparent (or semi-transparent) electrode, the opposite electrode 230 may have or include a layer formed of a metal having a small work function such as, for example, Li, Ca, LiF/Ca, LiF/Al, Al, Ag, Mg, or a combination thereof, and a transparent (or semi-transparent) conductive layer formed of ITO, IZO, ZnO, or In₂O₃. When the opposite electrode 230 is formed as a reflective electrode, the opposite electrode 230 may have or include a layer formed of Li, Ca, LiF/Ca, LiF/AI, Al, Ag, Mg, or a combination thereof. The configuration of the opposite electrode 230 and the material used to form the opposite electrode 230 are not limited to those described above, and various suitable modifications may be made to the opposite electrode 230.

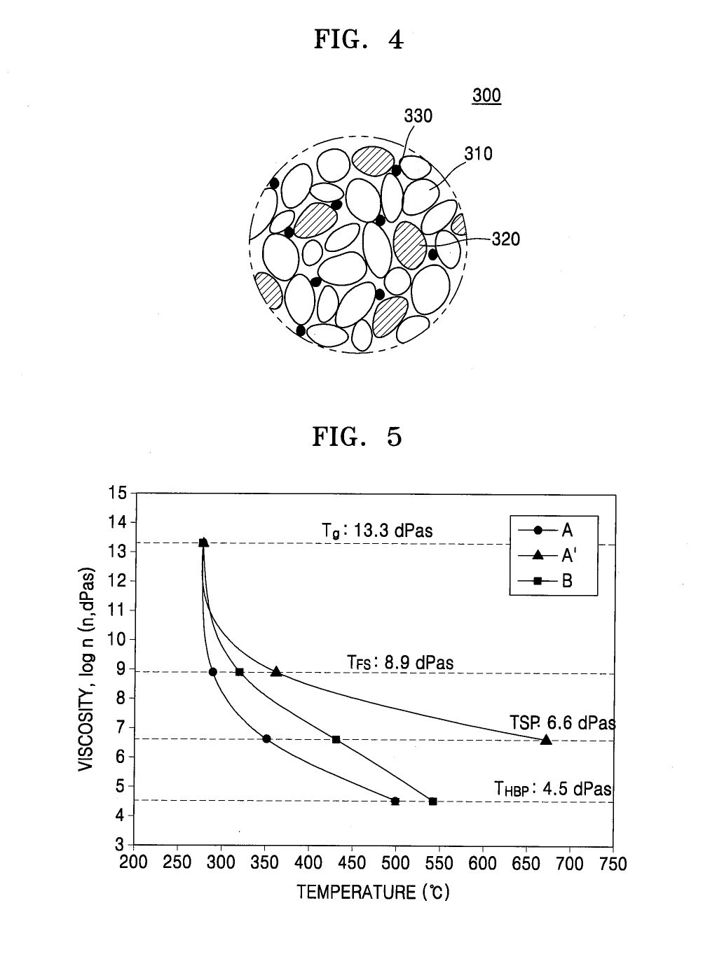

FIG. 4 is a magnified diagram of the circle portion IV of the sealing member 300 of FIG. 2.

Referring to FIG. 4, the sealing member 300 may include glass powder 310, a first filler 320, and a second filler 330. The sealing member 300 according to the present embodiment may be, for example, glass frit.

In some embodiments, to form the sealing member 300, a glass frit paste is made first. The glass frit paste includes solid glass powder 310 and a liquid vehicle. The glass powder 310 is a powder obtained by finely grinding glass typically having at least 4 compounds (or components). When a thickness of the sealing member 300 after firing is completed is equal to t_{frit}, dry milling is performed such that a diameter of the glass powder 310 (e.g., an average particle diameter of particles of the glass powder 310) is within 20% of the thickness t_{frit} (e.g., the average particle diameter of the particles of the glass powder 310 may be about 20% of the thickness WO. Since the thickness t_{frit} is about 3 to 30 μm, a mean particle diameter of the glass powder 310 may be about 0.6 to 6 μm.

The glass powder 310 according to the present embodiment may be formed of a V₂O₅-based material. In some embodiments, the glass powder 310 may be formed of V₂O₅ in an amount of 30 to 50 mol %, ZnO in an amount of 5 to 30 mol %, BaO in an amount of 0 to 20 mol %, TeO₂ in an amount of 0 to 30 mol %, Nb₂O₅ in an amount of 0 to 7 mol %, Al₂O₃ in an amount of 0 to 7 mol %, SiO₂ in an amount of 0 to 7 mol %, CuO in an amount of 0 to 5 mol %, MnO₂ in an amount of 0 to 5 mol %, or CaO in an amount of 0 to 5 mol %, based on the total number of moles of the glass powder 310.

Since the lower substrate 100 and the upper substrate 400 of the organic light-emitting display apparatus using the sealing member 300 are formed of glass having a low coefficient of thermal expansion (CTE) in order to sustain pattern precision before/after a thermal process, the glass powder 310, which is used to form the glass frit paste, may have (or needs to have) a CTE that is almost as similar as possible to respective CTEs of the lower substrate 100 and the upper substrate 400.

To attach the lower substrate 100 to the upper substrate 400 by partially melting the sealing member 300, the sealing member 300 may be (or needs to be) melted at a lowest temperature possible or practical, and then is smoothly flowed so as to form strong mechanical coupling between the lower substrate 100 and the upper substrate 400. This glass may have a physically high CTE, and may have an extremely weak impact resistance due to weak binding power between molecules. In other words, cracks are prone to be generated even with small external forces.

Thus, to compensate for the weak impact resistance and the high CTE of the glass powder 310, when the glass frit paste is formed, the first filler 320 including a ceramic material having a relatively low CTE is added to the glass powder 310 having a relatively high CTE. As such, the first filler 320 may be any suitable material as long as it has a CTE that is lower than that of the glass powder 310. To allow the first filler 320 to have a suitably or optimally stable structure and a low CTE, the first filler 320 may be formed to include a low thermal expansion ceramic having a CTE of (−90 to 50)*10⁻⁷/K or less. For example, the low thermal expansion ceramic may have a CTE of greater than 0 to 50*10⁻⁷/K, a CTE of 90*10⁻⁷/K or less, a CTE of greater than 0 to 90*10⁻⁷/K or less, or a CTE of (30 to 90)*10⁻⁷/K or less. The low thermal expansion ceramic may be, for example, zirconium (Zr)-based ceramic, cordierite, amorphous silica, eucryptite, aluminum titanate, spodumene, willemite, mulite, or zirconium tungstophosphate (ZWP). As such, by mixing the first filler 320 with the glass powder 310, a mechanical strength (e.g., a Young's modulus or fracture toughness) of the sealing member 300 may be increased.

However, when the sealing member 300 includes the first filler 320 as described above, the mechanical strength of the sealing member 300 may improve, but stresses are collected on the first filler 320 during a dropping impact. For example, organic light-emitting display apparatuses may be easily damaged or destroyed by dropping.

In addition, when the first filler 320 is added to the glass powder 310 as described above, flowability of the sealing member 300 sharply decreases. For example, since a glass transition temperature T_{g} of the sealing member 300 is lower than those of the lower substrate 100 and the upper substrate 400, chemical coupling does not occur on the interface between the lower substrate 100 and the sealing member 300 and the interface between the upper substrate 400 and the sealing member 300, and molecules of the sealing member 300 hold those of the lower substrate 100 and those of the upper substrate 400 on the interfaces. That is, for example, mechanical coupling occurs on the interfaces. High flowability of the sealing member 300 is needed to allow such mechanical coupling to smoothly occur. However, when only the first filler 320 is added to the glass powder 310 as described above, flowability of the sealing member 300 sharply decreases.

Consequently, due to the addition of the first filler 320 to the glass powder 310, the weak impact resistance of the glass powder 310 is complemented (e.g., compensated for), the high CTE thereof is compensated for, and the mechanical strength thereof improves. However, flowability, which is desirable or necessary when the sealing member 300 attaches the lower substrate 100 to the upper substrate 400, decreases.

Thus, in an organic light-emitting display apparatus according to an embodiment of the present disclosure, the second filler 330 including iron oxide in addition to the first filler 320 is added to the sealing member 300 so that the characteristics of the glass powder 310 may improve (or be compensated for) and a flowability problem that may occur when only the first filler 320 is added to the sealing member 300 may be dramatically addressed (e.g., dramatically reduced).

The second filler 330 may be formed by including iron oxide, and the iron oxide used to form the second filler 330 may be Fe₂O₃. The second filler 330 may be formed to have crystalline particles with diameters of 0.1 to 2 μm.

As described above, the sealing member 300 may include the glass powder 310, the first filler 320, and the second filler 330. In some embodiments, the sealing member 300 may include the glass powder 310 in an amount of 50 to 90 wt %, the first filler 320 in an amount of 1 to 50 wt %, and the second filler 330 in an amount of 1 to 5 wt %, based on the total weight of the sealing member 300. For example, the sealing member 300 may include the glass powder 310 in an amount of 70 to 85 wt %, the first filler 320 in an amount of 25 to 30 wt %, and the second filler 330 in an amount of 1 to 3 wt %.

As the sealing member 300 includes the second filler 330 including iron oxide in addition to the first filler 320, the mechanical strength of the sealing member 300 may improve and flowability thereof may be dramatically complemented (e.g., substantially increased).

FIG. 5 is a graph showing measured viscosity of a sealing material according to an embodiment of the present disclosure and measured viscosity of a sealing material of a comparative example with respect to temperature.

Referring to FIG. 5, showing measurement of viscosity-temperature characteristics due to addition of the second filler 330 to the sealing member 300, the X axis represents a temperature gradient (represents the temperature of the sealing member 300), and the Y axis represents a variation in viscosity versus temperature. The graph of FIG. 5 shows A, A′, and B as comparative examples and an embodiment. A denotes Comparative Example 1, A′ denotes Comparative Example 2, and B denotes an embodiment of the present disclosure. To obtain the graph of FIG. 5, an upper surface of a glass substrate is coated with A, A′, and B, and then respective characteristics of A, A′, and B were measured. FIG. 5 shows viscosity versus temperature when B is a material for sealing a display apparatus according to an embodiment of the present disclosure, viscosity versus temperature when A is a glass frit paste formed of only the glass powder 310 without addition of fillers according to Comparative Example 1, and viscosity versus temperature when A′ is a result of adding only the first filler 320 to the glass frit paste A according to Comparative Example 2.

With regard to a definition of a temperature according to viscosity, a temperature at which the viscosity is 13.3 is defined as a glass transition temperature T_{g}, a temperature at which the viscosity is 8.9 is defined as a temperature T_{FS} at which “First shrinkage”, that is, for example, shrinkage, starts to occur, a temperature at which the viscosity is 7.9 is defined as a temperature at which “Maximum shrinkage”, that is, for example, maximum or substantially maximum shrinkage, occurs, a temperature at which the viscosity is 6.6 is defined as a temperature at “Softening point”, that is, for example, a temperature _{TSP} at which glass starts to melt, a temperature at which the viscosity is 4.5 is defined as a temperature at “Half ball point”, that is, for example, a temperature T_{HPS} at which glass melts and turns into a half ball, and a temperature at which the viscosity is 3.1 is defined as a temperature at “Flow point”, that is, for example, a temperature at which glass completely or substantially completely melts and spreads.

Referring to FIG. 5, each of A, A′, and B has a glass transition temperature T_{g} at about 276° C. When the temperature gradually increases from the glass transition temperature T_{g}, first, a first shrinkage T_{FS} of A is about 274° C., a softening point T_{SP} thereof is about 331° C., and a half ball point T_{HPB} thereof is about 500° C. A first shrinkage T_{FS} of A′, which is a result of adding only the first filler 320 to the glass frit paste A, is about 270° C., a softening point T_{SP} thereof is about 668° C., and a half ball point T_{HPB} thereof is a high enough value to deviate from the measured temperature range (the T_{HPB} was outside of the measured range). In other words, the temperature of A′, which is a result of adding only the first filler 320 to the glass frit paste A, greatly increased to reach an identical or substantially identical viscosity, as compared with A and B. From this, it is seen that the mechanical strength of a sealing material is increased due to addition of the first filler 320 but flowability thereof greatly decreases.

In the sealing material B to which the second filler 330 including iron oxide, namely, Fe₂O₃, has been added, a first shrinkage T_{FS} is about 280° C., a softening point T_{SP} is about 434° C., and a half ball point T_{HPB} is about 543° C., which are slightly higher than those of A but are greatly lower than those of A′. From this, it is seen that, due to addition of the second filler 330, the mechanical strength of a sealing material is complemented and flowability thereof is also greatly improved.

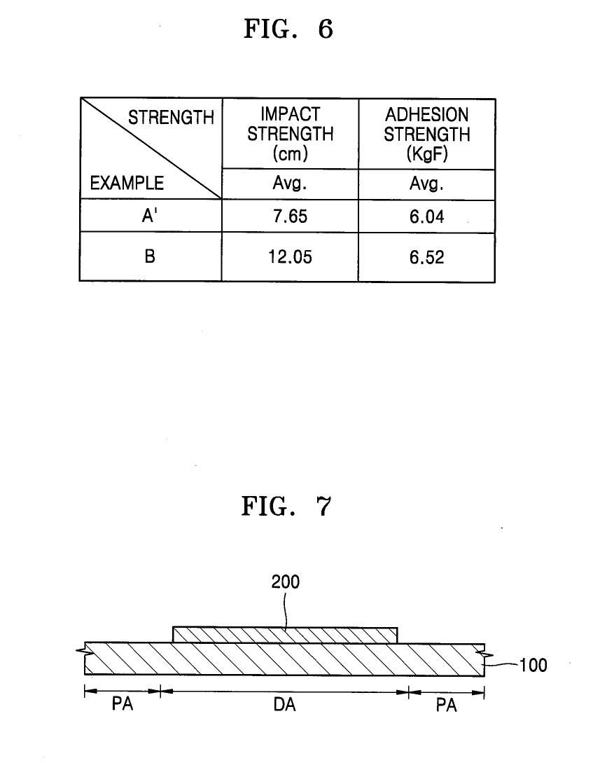

FIG. 6 is a table showing measured values of mechanical strengths of the sealing material B according to an embodiment of the present disclosure and the sealing material A′ according to Comparative Example 2 of FIG. 5.

Referring to FIG. 6, Embodiment B is the display apparatus sealing material according to an embodiment of the present disclosure, and Comparative Example 2 (sealing material A′) is a result of adding only the first filler 320 to the glass frit paste A. FIG. 6 shows measured values of mechanical strengths of organic light-emitting display panels after the organic light-emitting display panels are respectively sealed using Comparative Example 2 (sealing material A′) and one Embodiment (sealing material B). In other words, sealing capabilities of the sealing materials A′ and B were compared and evaluated by measuring adhesion strengths and impact strengths of the panels. An impact strength (dynamic strength) is calculated from a height at which the sealing member 300 is destroyed by dropping a 300 g weight on the respective centers of the upper surfaces of 20 panels at a time for each condition of a sealing material. An adhesion strength (static strength) is calculated from a force with which the sealing member 300 is destroyed by vertically pulling a panel after attaching an edge of the sealing member 300 of the panel to a mount.

Referring to an experimental result of the impact strength, the sealing member 300 of a display panel according to Comparative Example 2 (sealing material A′) was destroyed at an average height of 7.65 cm, and the sealing member 300 of a display panel including the second filler 330 according to one Embodiment (sealing material B) was destroyed at an average height of 12.05 cm. For example, the sealing material including the second filler 330 according to the Embodiment (sealing material B) has a high impact strength that is, for example, almost twice that of Comparative Example 2 (sealing material A′) against an external impact.

Referring to an experimental result of the adhesion strength, the sealing member 300 of a display panel according to Comparative Example 2 (sealing material A′) was destroyed when the display panel was pulled with an average force of 6.04 kilogram-force (KgF), and the sealing member 300 of a display panel including the second filler 330 according to one Embodiment (sealing material B) was destroyed when the display panel was pulled with an average force of 6.52 KgF. In other words, the sealing material including the second filler 330 according to one Embodiment (sealing material B) has an improved capability of adhering the lower and upper substrates 100 and 400 together, as compared with Comparative Example 2 (sealing material A′).

Although only an organic apparatus sealing material and an organic light-emitting display apparatus including the organic apparatus sealing material have been described above, embodiments of the present disclosure are not limited thereto. For example, a method of manufacturing the organic apparatus sealing material and the organic light-emitting display apparatus including the organic apparatus sealing material may belong within the scope of the present disclosure.

FIGS. 7-9 are cross-sectional views schematically illustrating a method of manufacturing an organic light-emitting display apparatus, according to an embodiment of the present disclosure.

Referring to FIG. 7, a lower substrate 100 having a display area DA and a peripheral area PA surrounding the display area DA may be first prepared or secured. The lower substrate 100 may be formed of a transparent glass material containing SiO₂ as a main component. However, the material used to form the lower substrate 100 is not limited thereto, and the lower substrate 100 may be formed of a transparent plastic material. The plastic material used to form the lower substrate 100 may be an organic insulating material selected from the group consisting of polyethersulphone (PES), polyacrylate (PAR), polyetherimide (PEI), polyethylene naphthalate (PEN), polyethylene terephthalate (PET), polyphenylene sulfide (PPS), polyallylate, polyimide, polycarbonate (PC), cellulose triacetate (TAC), and cellulose acetate propionate (CAP).

As for a bottom-emission organic light-emitting display apparatus that displays an image on or through the lower substrate 100, the lower substrate 100 may be formed of a transparent material. However, as for a top-emission organic light-emitting display apparatus that displays an image in a direction away from the lower substrate 100, the lower substrate 100 does not need to be formed of a transparent material (e.g., the lower substrate may include a reflective material). In this case, the lower substrate 100 may be formed of a metal. The metal that may be used to form the lower substrate 100 may include at least one metal selected from the group consisting of iron (Fe), chromium (Cr), manganese (Mn), nickel (Ni), titanium (Ti), molybdenum (Mo), stainless steel (SUS), an Invar alloy, an Inconel alloy, and a Kovar alloy. The lower substrate may include carbon (C) in addition to or instead of the metal. However, the lower substrate 100 is not limited thereto.

The display unit 200 may be on (e.g., formed on) the display area DA of the lower substrate 100. The display unit 200 may include a plurality of pixels PX. As described above, each pixel PX may include the plurality of thin film transistors TFT and the OLEDs 240 that are electrically coupled or connected to the thin film transistors TFT. A structure of the display unit 200 and a method of manufacturing the display unit 200 have already been described above in detail with reference to FIG. 3, and therefore, it is not necessary to repeat that description here.

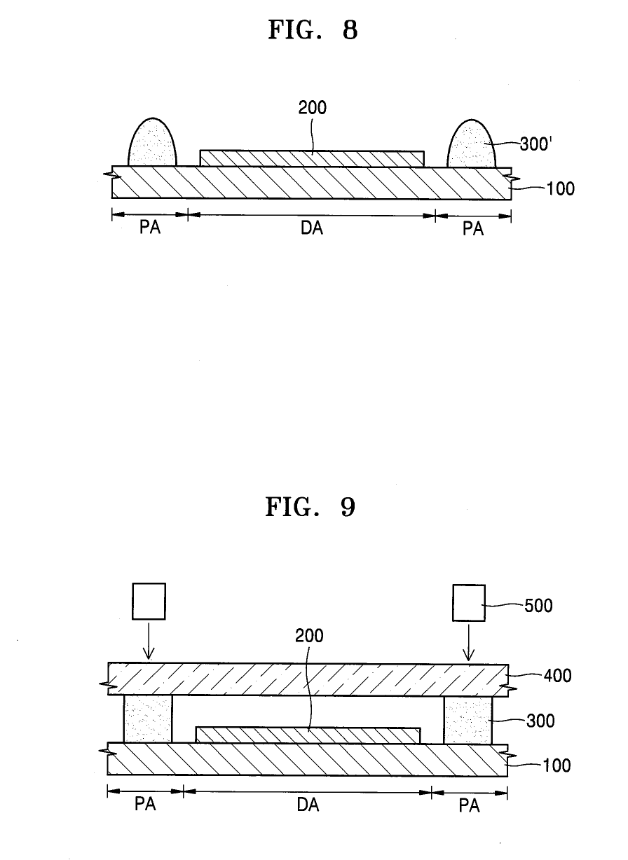

Referring to FIG. 8, the peripheral area PA of the lower substrate 100 may be coated with a sealing material 300′. The sealing member 300′ may include the glass powder 310, the first filler 320 including a ceramic material, and the second filler 330 including iron oxide.

The glass powder 310 may be formed of a V₂O₅-based material, and, for example, may be formed of V₂O₅ in an amount of 30 to 50 mol %, ZnO in an amount of 5 to 30 mol %, BaO in an amount of 0 to 20 mol %, TeO₂ in an amount of 0 to 30 mol %, Nb1O₅ in an amount of 0 to 7 mol %, Al₂O₃ in an amount of 0 to 7 mol %, SiO₂ in an amount of 0 to 7 mol %, CuO in an amount of 0 to 5 mol %, MnO₂ in an amount of 0 to 5 mol %, or CaO in an amount of 0 to 5 mol %, based on the total number of moles of the glass powder 310.

The glass powder 310 may have a physically high CTE, and may have an extremely weak impact resistance due to weak coupling power between molecules (e.g., between molecules of the glass powder 310). Thus, to compensate for the weak impact resistance and the high CTE of the glass powder 310, when the glass frit paste is formed, the first filler 320 including a ceramic material with a relatively low CTE is added to the glass powder 310 having a relatively high CTE.

As such, the first filler 320 may be any suitable material as long as it has a CTE that is lower than that of the glass powder 310. To allow the first filler 320 to have a suitably or optimally stable structure and a low CTE, the first filler 320 may be formed to include a low thermal expansion ceramic having a CTE of (−90 to 50)*10⁻⁷/K or less. For example, the low thermal expansion ceramic may have a CTE of greater than 0 to 50*10⁻⁷/K, a CTE of 90*10⁻⁷/K or less, a CTE of greater than 0 to 90*10⁻⁷/K or less, or a CTE of (30 to 90)*10⁻⁷/K or less. The low thermal expansion ceramic may be, for example, zirconium (Zr)-based ceramic, cordierite, amorphous silica, eucryptite, aluminum titanate, spodumene, willemite, mulite, or ZWP. As such, by mixing the first filler 320 with the glass powder 310, a mechanical strength of the sealing member 300 may be increased.

Due to the addition of the first filler 320 to the glass powder 310, the weak impact resistance of the glass powder 310 is complemented (e.g., compensated for), the high CTE thereof is compensated for, and the mechanical strength thereof improves. However, flowability, which is desirable or necessary when the sealing member 300 attaches the lower substrate 100 to the upper substrate 400, decreases.

Thus, in an organic light-emitting display apparatus according to an embodiment of the present disclosure, the second filler 330 including iron oxide in addition to the first filler 320 is added to the sealing member 300 so that the characteristics of the glass powder 310 may improve (or be compensated for) and a flowability problem that may occur when only the first filler 320 is added to the sealing member 300 may be dramatically addressed (e.g., dramatically reduced).

The second filler 330 may be formed by including iron oxide, and the iron oxide used to form the second filler 330 may be Fe₂O₃. The second filler 330 may be formed to have crystalline particles with diameters of 0.1 to 2 μm.

As described above, the sealing member 300 may include the glass powder 310, the first filler 320, and the second filler 330. In this case, the sealing member 300 may include the glass powder 310 in an amount of 50 to 90 wt %, the first filler 320 in an amount of 1 to 50 wt %, and the second filler 330 in an amount of 1 to 5 wt %, based on the total weight of the sealing member 300. For example, the sealing member 300 may include the glass powder 310 in an amount of 70 to 85 wt %, the first filler 320 in an amount of 25 to 30 wt %, and the second filler 330 in an amount of 1 to 3 wt %.

Thereafter, referring to FIG. 9, the upper substrate 400 may be positioned on the lower substrate 100, and then the lower substrate 100 and the upper substrate 400 may be adhered together via the sealing member 300. For example, after the upper substrate 400 may be positioned on the sealing member 300 on (e.g., formed on) the lower substrate 100, the upper substrate 400 including the sealing member 300 may be irradiated with lasers 500 to thereby adhere the upper substrate 400 and the lower substrate 100 together. The lower substrate 100 on which the sealing member 300 is formed may be irradiated with lasers to adhere the upper substrate 400 and the lower substrate 100 together. For example, adhering the lower substrate to the upper substrate may include adhering the lower substrate to the upper substrate by radiating a laser beam to the upper substrate or the lower substrate on which the sealing material is formed.

As the sealing member 300 includes the second filler 330 including iron oxide in addition to the first filler 320, the mechanical strength of the sealing member 300 may improve and flowability thereof may be dramatically complemented (e.g., substantially increased).

According to one or more exemplary embodiments as described above, a material for sealing a display apparatus, the material having an improved mechanical strength and improved flowability, an organic light-emitting display apparatus including the material, and a method of manufacturing the organic light-emitting display apparatus may be obtained. Of course, the scope of the present disclosure is not restricted by this effect.

It should be understood that the exemplary embodiments described herein should be considered in a descriptive sense only and not for purposes of limitation. Descriptions of features or aspects within each embodiment should typically be considered as available for other similar features or aspects in other embodiments.

While the subject matter of the present disclosure has been shown and described with reference to exemplary embodiments thereof, it will be understood by those of ordinary skill in the art that various changes in form and details may be made therein without departing from the spirit and scope of the present invention as defined by the following claims, and equivalents thereof.

What is claimed is:

1. An organic light-emitting display apparatus comprising:
a lower substrate having a display area and a peripheral area around the display area;
a display unit on the display area of the lower substrate;
an upper substrate on the display unit and facing the lower substrate; and
a sealing member on the peripheral area of the lower substrate to adhere the lower substrate and the upper substrate together, the sealing member comprising a glass powder, a first filler comprising a ceramic material, and a second filler comprising iron oxide.

2. The organic light-emitting display apparatus of claim 1, wherein the iron oxide is Fe₂O₃.

3. The organic light-emitting display apparatus of claim 1, wherein a crystalline particle of the second filler has a diameter of about 0.1 to about 2 μm.

4. The organic light-emitting display apparatus of claim 1, wherein the first filler comprises a low thermal expansion ceramic material having a Coefficient of Thermal Expansion (CTE) of (−90 to 50)*10⁻⁷/K or less.

5. The organic light-emitting display apparatus of claim 1, wherein the first filler comprises at least one selected from the group consisting zirconium (Zr)-based ceramic, cordierite, amorphous silica, eucryptite, aluminum titanate, spodumene, willemite, and mulite.

6. The organic light-emitting display apparatus of claim 1, wherein the glass powder is formed of V₂O₅ in an amount of 30 to 50 mol %, ZnO in an amount of 5 to 30 mol %, BaO in an amount of 0 to 20 mol %, TeO₂ in an amount of 0 to 30 mol %, Nb₂O₅ in an amount of 0 to 7 mol %, Al₂O₃ in an amount of 0 to 7 mol %, SiO₂ in an amount of 0 to 7 mol %, CuO in an amount of 0 to 5 mol %, MnO₂ in an amount of 0 to 5 mol %, and CaO in an amount of 0 to 5 mol %.

7. The organic light-emitting display apparatus of claim 1, wherein the sealing member comprises the glass powder in an amount of 50 to 90 wt %, the first filler in an amount of 1 to 50 wt %, and the second filler in an amount of 1 to 5 wt %.

8. A method of manufacturing an organic light-emitting display apparatus, the method comprising:
preparing a lower substrate having a display area and a peripheral area around the display area;
forming a display unit on the display area of the lower substrate;
forming a sealing material on the peripheral area of the lower substrate, the sealing material comprising a glass powder, a first filler comprising a ceramic material, and a second filler comprising iron oxide; and
positioning the upper substrate on the lower substrate and adhering the lower substrate to the upper substrate via the sealing material.

9. The method of claim 8, wherein the iron oxide is Fe₂O₃.

10. The method of claim 8, wherein a crystalline particle of the second filler has a diameter of about 0.1 to about 2 μm.

11. The method of claim 8, wherein the first filler comprises a low thermal expansion ceramic material having a Coefficient of Thermal Expansion (CTE) of (−90 to 50)*10⁻⁷/K or less.

12. The method of claim 8, wherein the first filler comprises at least one selected from the group consisting zirconium (Zr)-based ceramic, cordierite, amorphous silica, eucryptite, aluminum titanate, spodumene, willemite, and mulite.

13. The method of claim 8, wherein the glass powder is formed of V₂O₅ in an amount of 30 to 50 mol %, ZnO in an amount of 5 to 30 mol %, BaO in an amount of 0 to 20 mol %, TeO₂ in an amount of 0 to 30 mol %, Nb₂O₅ in an amount of 0 to 7 mol %, Al₂O₃ in an amount of 0 to 7 mol %, SiO₂ in an amount of 0 to 7 mol %, CuO in an amount of 0 to 5 mol %, MnO₂ in an amount of 0 to 5 mol %, and CaO in an amount of 0 to 5 mol %.

14. The method of claim 8, wherein the sealing member comprises the glass powder in an amount of 50 to 90 wt %, the first filler in an amount of 1 to 50 wt %, and the second filler in an amount of 1 to 5 wt %.

15. The method of claim 8, wherein the adhering of the lower substrate to the upper substrate comprises adhering the lower substrate to the upper substrate by radiating a laser beam to the upper substrate or the lower substrate on which the sealing material is formed.

16. A material for sealing a display apparatus, the material comprising:
V₂O₅-based glass powder;
a first filler comprising a ceramic material; and
a second filler comprising iron oxide.

17. The material of claim 16, wherein the iron oxide is Fe₂O₃.

18. The material of claim 16, wherein a crystalline particle of the second filler has a diameter of about 0.1 to about 2 μm.

19. The material of claim 16, wherein the first filler comprises a low thermal expansion ceramic material having a Coefficient of Thermal Expansion (CTE) of (30 to 90)*10⁻⁷/K or less.

20. The material of claim 16, wherein the first filler comprises at least one selected from the group consisting zirconium (Zr)-based ceramic, cordierite, amorphous silica, eucryptite, aluminum titanate, spodumene, willemite, and mulite.

21. The material of claim 16, wherein the glass powder is formed of V₂O₅ in an amount of 30 to 50 mol %, ZnO in an amount of 5 to 30 mol %, BaO in an amount of 0 to 20 mol %, TeO₂ in an amount of 0 to 30 mol %, Nb₂O₅ in an amount of 0 to 7 mol %, Al₂O₃ in an amount of 0 to 7 mol %, SiO₂ in an amount of 0 to 7 mol %, CuO in an amount of 0 to 5 mol %, MnO₂ in an amount of 0 to 5 mol %, and CaO in an amount of 0 to 5 mol %.

22. The material of claim 16, wherein the sealing member comprises the glass powder in an amount of 50 to 90 wt %, the first filler in an amount of 1 to 50 wt %, and the second filler in an amount of 1 to 5 wt %.
